(19) United States
(12) Patent Application Publication
(10) Pub. No.: US 2015/0115228 A1
(43) Pub. Date: Apr. 30, 2015

(54) Light Emitting Device

(71) Applicant: Industrial Technology Research Institute, Hsinchu (TW)

(72) Inventors: Yi-Ping LIN, Hsinchu (TW); Jung-Yu LI, Hsinchu (TW); Guan-Yu CHEN, Hsinchu (TW); Jin-Han WU, Hsinchu (TW); Cheng-Hung LI, Hsinchu (TW); Shih-Pu CHEN, Hsinchu (TW)

(73) Assignee: Industrial Technology Research Institute, Hsinchu (TW)

(21) Appl. No.: 14/137,764

(22) Filed: Dec. 20, 2013

(30) Foreign Application Priority Data
Oct. 30, 2013 (TW) 102139269

(51) Int. Cl. H01L 51/52; H01L 51/50

(52) U.S. Cl. CPC H01L 51/5203; H01L 51/504
USPC 257/40

(57) ABSTRACT

A light emitting device is disclosed, including a first electrode layer, an organic light emitting layer disposed on the first electrode layer, and a second electrode layer disposed on the organic light emitting layer. The organic light emitting layer is sandwiched between the first electrode layer and the second electrode layer. The second electrode layer is patterned to form a plurality of electrode patterns arranged with different densities, thereby generating three-dimensional, greyscale or full-color images.

### CROSS-REFERENCE TO RELATED APPLICATIONS

This application claims priority to Taiwanese Patent Application No. 102139269, filed on Oct. 30, 2013. The entirety of the above-mentioned patent application is hereby incorporated by reference herein and made a part of this specification.

### BACKGROUND

1. Technical Field

The present disclosure relates to light emitting device, and, more particularly, to an organic light emitting device that generates grayscale, full-color, three-dimensional and dynamic images.

2. Description of Related Art

Organic light emitting diodes (OLED) are regarded as the most promising light sources in the future. Compared with a conventional fluorescent lamp or a solid state light source such as a light emitting diode, an OLED has a light weight and a high color rendering index, generates low glare light, and is flexible and transparent. Therefore, the application of the OLEDs on illumination can be much diversified.

Currently, full-color images can be generated by passive matrix OLEDs (PMOLEDs) that control upper and lower electrodes of each pixel, or generated by active matrix OLEDs (AMOLEDs) that control brightness of each pixel through a thin film transistor (TFT).

However, to control the luminous intensity of each pixel so as to generate full-color/grayscale images, the voltage applied to each pixel needs to be controlled through a thin film transistor, thus complicating the process. Further, TFT driving control circuits are costly and hinder the development of low-cost organic light emitting devices.

Therefore, how to overcome the above-described drawbacks has become urgent.

### SUMMARY

In view of the above-described drawbacks, the present disclosure provides a light emitting device, which comprises: a first electrode layer; an organic light emitting layer disposed on the first electrode layer; and a second electrode layer disposed on the organic light emitting layer, wherein the organic light emitting layer is sandwiched between the first electrode layer and the second electrode layer, and the second electrode layer is patterned to form a plurality of electrode patterns arranged with different densities. A voltage can be applied between the first electrode layer and the second electrode layer so as for the light emitting device to generate a greyscale image.

Further, the organic light emitting layer can be performed by a color separation process to be a plurality of monochromatic blocks that correspond to the electrode patterns, respectively. As such, a voltage can be applied between the first electrode layer and the second electrode layer so as for the light emitting device to generate a full-color/greyscale image.

The present disclosure provides another light emitting device, which comprises: a first electrode layer; an organic light emitting layer disposed on the first electrode layer; and a second electrode layer disposed on the organic light emitting layer, wherein the organic light emitting layer is sandwiched between the first electrode layer and the second electrode layer, the second electrode layer is patterned to form a plurality of electrode patterns arranged with different densities, and the electrode patterns are performed by a color separation process to be a plurality of electrode pattern groups that are arranged in an alternate manner.

In an embodiment, the electrode pattern groups display a same image, and a same voltage is applied to the electrode pattern groups at a same time. As such, the light emitting device generates a three-dimensional image.

In another embodiment, the electrode pattern groups display different images, and a same or different voltages are applied to the electrode pattern groups at different times. As such, the light emitting device generates a dynamic image.

The present disclosure provides yet another light emitting device, which comprises: a first electrode layer; a first organic light emitting layer disposed on the first electrode layer; a second organic light emitting layer disposed on the first organic light emitting layer; and a second electrode layer disposed on the second organic light emitting layer, wherein the first organic light emitting layer is sandwiched between the first electrode layer and the second organic light emitting layer, the second organic light emitting layer is sandwiched between the second electrode layer and the first organic light emitting layer, and the second electrode layer is patterned to form a plurality of electrode patterns arranged with different densities. Further, an electric charge generating layer can be disposed between the first organic light emitting layer and the second organic light emitting layer.

In an embodiment, a voltage is applied between the first electrode layer and the second electrode layer. As such, the light emitting device generates a three-dimensional image.

In another embodiment, the light emitting device further comprises a third electrode layer, an insulating layer and a fourth electrode layer that are sequentially stacked between the first organic light emitting layer and the second organic light emitting layer, wherein the third electrode layer is patterned to form a plurality of electrode patterns arranged with different densities, the electrode patterns of the second electrode layer display an image that is different from an image displayed by the electrode patterns of the third electrode layer, and a same or different voltages are applied to the second electrode layer and the third electrode layer at different times. As such, the light emitting device generates a dynamic image.

According to the present disclosure, the second electrode layer is patterned to form a plurality of electrode patterns arranged with different densities. As such, when a voltage is applied between the first electrode layer and the second electrode layer, the light emitting device according to the present disclosure generates a grayscale image. Further, by performing a color separation process on the organic light emitting layer to form a plurality of monochromatic blocks, the light emitting device generates a full-color/grayscale image. Furthermore, by arranging the electrode patterns in a vertical direction or a horizontal direction and applying voltages of suitable values and time sequences on the electrode layers, the light emitting device according to the present disclosure can generate a three-dimensional or dynamic image in full color/greyscale. Therefore, the present disclosure eliminates the need to control the brightness of each pixel through a thin film transistor as in the prior art.

### BRIEF DESCRIPTION OF DRAWINGS

FIG. 1A is a schematic cross-sectional view of a light emitting device according to a first embodiment of the present disclosure;

FIG. 1B is a schematic upper view of the light emitting device according to the first embodiment of the present disclosure;

FIG. 1C shows a greyscale image generated by the light emitting device according to the first embodiment of the present disclosure;

FIG. 2A is a schematic cross-sectional view of a light emitting device according to a second embodiment of the present disclosure;

FIG. 2B is a schematic upper view of the light emitting device according to the second embodiment of the present disclosure;

FIG. 2C shows a greyscale image generated by the light emitting device according to the second embodiment of the present disclosure;

FIG. 3A is a schematic cross-sectional view of a light emitting device according to a third embodiment of the present disclosure;

FIG. 3B is a schematic upper view of the light emitting device according to the third embodiment of the present disclosure;

FIG. 4 is a schematic cross-sectional view of a light emitting device according to a fourth embodiment of the present disclosure;

FIG. 5A is a schematic cross-sectional view of a light emitting device according to a fifth embodiment of the present disclosure;

FIG. 5B shows images displayed by the light emitting device according to the fifth embodiment of the present disclosure;

FIG. 6A is a schematic cross-sectional view of a light emitting device according to a sixth embodiment of the present disclosure;

FIG. 6B shows images displayed by the light emitting device according to the sixth embodiment of the present disclosure;

FIG. 7A is a schematic cross-sectional view of a light emitting device according to a seventh embodiment of the present disclosure;

FIG. 7B shows images displayed by the light emitting device according to the seventh embodiment of the present disclosure;

FIG. 8A is a schematic cross-sectional view of a light emitting device according to an eighth embodiment of the present disclosure; and

FIG. 8B shows images displayed by the light emitting device according to the eighth embodiment of the present disclosure.

### DETAILED DESCRIPTION

In the following detailed description, for purposes of explanation, numerous specific details are set forth in order to provide a through understanding of the disclosed embodiments. It will be apparent, however, that one or more embodiments may be practiced without these specific details. In other instances, well-known structures and devices are schematically shown in order to simplify the drawing.

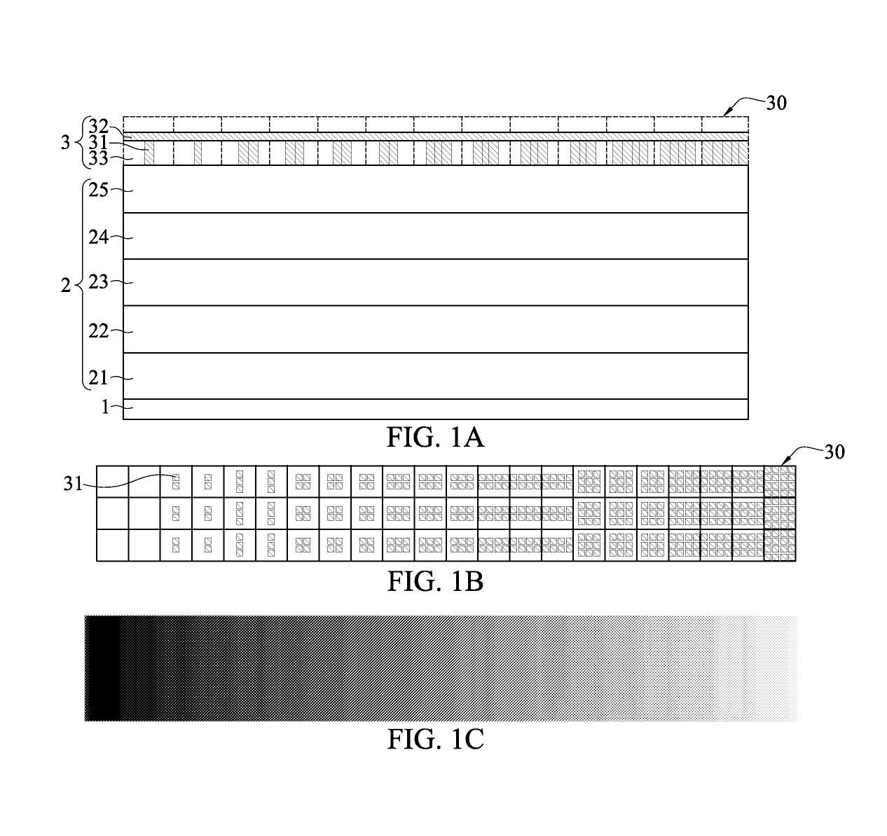

FIGS. 1A and 1B are schematic cross-sectional and upper view of a light emitting device according to a first embodiment of the present disclosure, respectively. Referring to FIG. 1A, the light emitting device has a first electrode layer 1, an organic light emitting layer 2, and a second electrode layer 3 sequentially stacked on one another.

The first electrode layer 1 is an anode electrode layer. The first electrode layer 1 is, but not limited to, a transparent electrode layer and made of ITO, IZO or any other transparent conductor material.

The organic light emitting layer 2 is disposed on the first electrode layer 1 and comprises a hole injection layer (HIL) 21, a hole transport layer (HTL) 22, an emitting layer (EML) 23, an electron transport layer (ETL) 24, and an electron injection layer (EIL) 25.

The second electrode layer 3 is disposed on the organic light emitting layer 2, and the organic light emitting layer 2 is sandwiched between the first electrode layer 1 and the second electrode layer 3. The second electrode layer 3 is a cathode electrode layer. The second electrode layer 3 is, but not limited to, a reflective electrode layer and made of metal. In another embodiment, both the first electrode layer 1 and the second electrode layer 3 are transparent electrode layers.

When a voltage is applied between the first electrode layer 1 and the second electrode layer 3, holes from the first electrode layer 1 are injected through the hole injection layer 21 to the hole transport layer 22 and transported through the hole transport layer 22 to the emitting layer 23, and electrons from the second electrode layer 3 are injected through the electron injection layer 25 to the electron transport layer 24 and transported through the electron transport layer 24 to the emitting layer 23. When the holes and the electrons are recombined in the emitting layer 23, light is generated.

The second electrode layer 3 is patterned to form a plurality of electrode patterns 31 arranged with different densities, which is detailed as follows.

Referring to FIGS. 1A and 1B, the second electrode layer 3 is divided into a plurality of pixels 30 each having a different number of the electrode patterns 31. Some of the electrode patterns 31 are connected through planar electrodes 32, and the others are separated by an insulating material 33. In the first embodiment, the electrode patterns 31 have a same size but different pitches. The pitch refers to a distance between the centers of two adjacent electrode patterns. FIG. 1C shows a grayscale image generated by the light emitting device according to the first embodiment of the present disclosure.

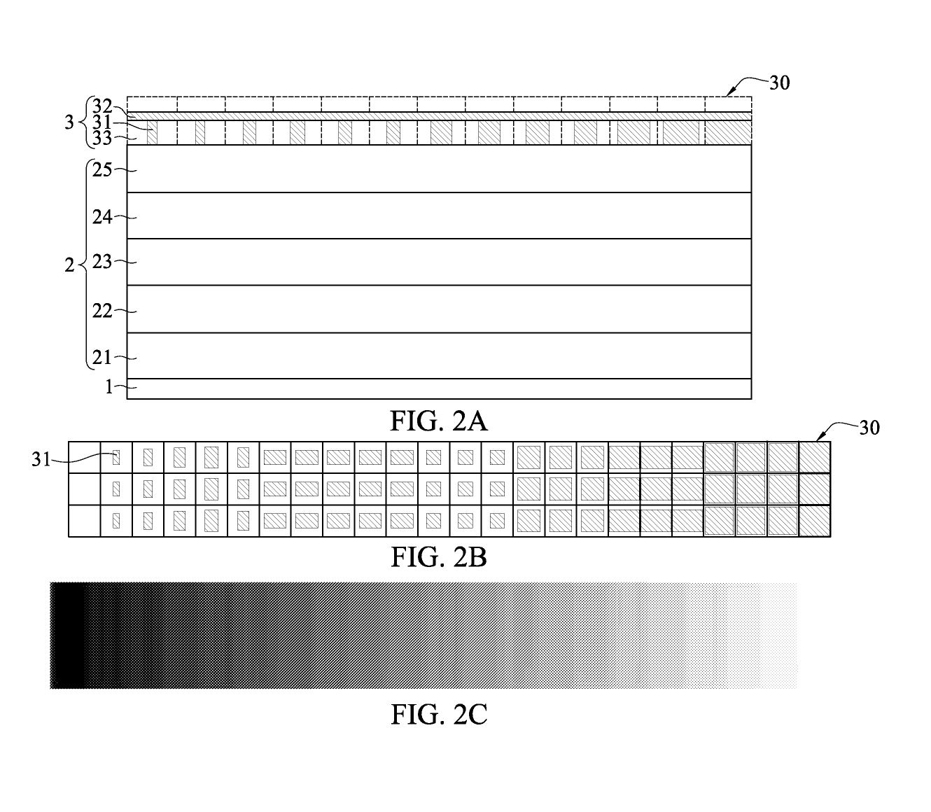

FIGS. 2A and 2B are schematic cross-sectional and upper view of a light emitting device according to a second embodiment of the present disclosure, respectively. Referring to FIGS. 2A and 2B, the second embodiment differs from the first embodiment in that the second electrode layer 3 of the light emitting device of the second embodiment is divided into a plurality of pixels 30 each having a same number of the electrode patterns 31. Some of the electrode patterns 31 are connected through the planar electrodes 32, and the others are separated by the insulating material 33. In the second embodiment, the electrode patterns 31 have different sizes but a same pitch. FIG. 2C shows a greyscale image generated by the light emitting device according to the second embodiment of the present disclosure.

According to the first and second embodiments, by arranging the electrode patterns 31 of the second electrode layer 3 with different densities, including changing the sizes or pitches of the electrode patterns or the number of the electrode patterns of each pixel, the light emitting device can be controlled to generate a greyscale image.

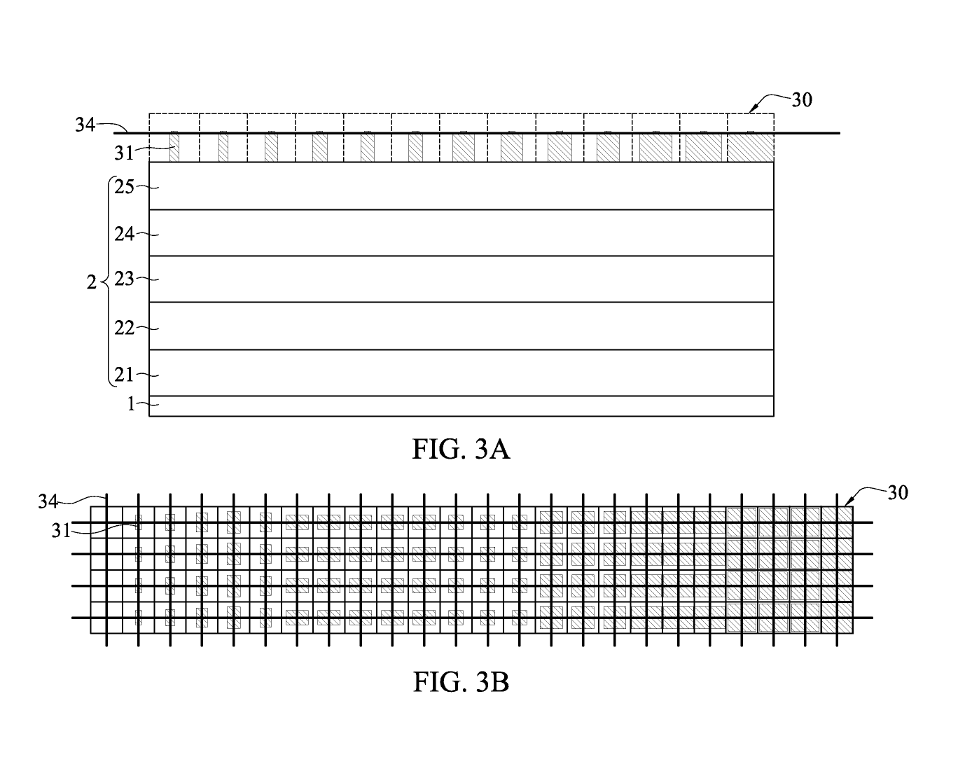

FIGS. 3A and 3B are schematic cross-sectional and upper view of a light emitting device according to a third embodiment of the present disclosure, respectively. The third embodiment differs from the first and second embodiments in that the electrode patterns 31 of the light emitting device of the third embodiment are connected through conductive lines 34 that are, for example, in a mesh pattern, and no insulating material is filled between any two of the electrode patterns 31.

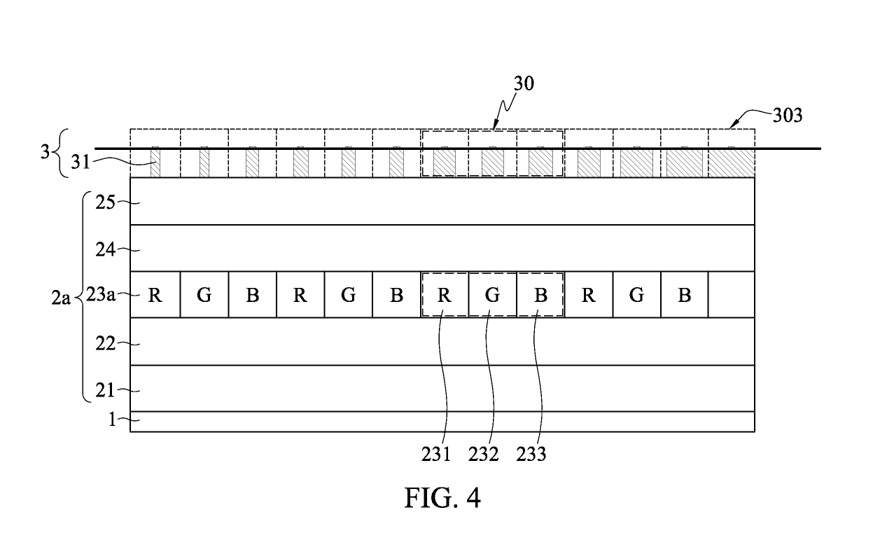

FIG. 4 is a schematic cross-sectional view of a light emitting device according to a fourth embodiment of the present disclosure. Referring to FIG. 4, the emitting layer 23a of the organic light emitting layer 2a is performed by a color separation proves to be a plurality of monochromatic blocks 231, 232 and 233, i.e., red blocks (R), blue blocks (B) and green blocks (G) corresponding to the pixels 30. The electrode patterns 31 of the second electrode layer 3 correspond to the monochromatic blocks 231, 232, 233, respectively. Referring to FIG. 4, each pixel 30 of the second electrode layer 3 is divided into a plurality of sub-pixels 303 each having an electrode pattern 31 corresponding to one of the monochromatic blocks 231, 232 and 233. Therefore, by arranging the electrode patterns 31 with different densities, the monochromatic blocks 231, 232 and 233 emit lights of different brightness so as to generate a full-color image.

Referring to FIGS. 1A to 1C, 2A to 2C and 4, by arranging the electrode patterns 31 of the second electrode layer 3 with different densities, including changing the sizes or pitches of the electrode patterns or the number of the electrode patterns of each pixel, and causing each of the electrode patterns 31 of the second electrode layer 3 to correspond to one of the monochromatic blocks 231, 232 or 233 of the emitting layer 23a of the organic light emitting layer 2a, the light emitting device can be controlled to generate a full-color/grayscale image.

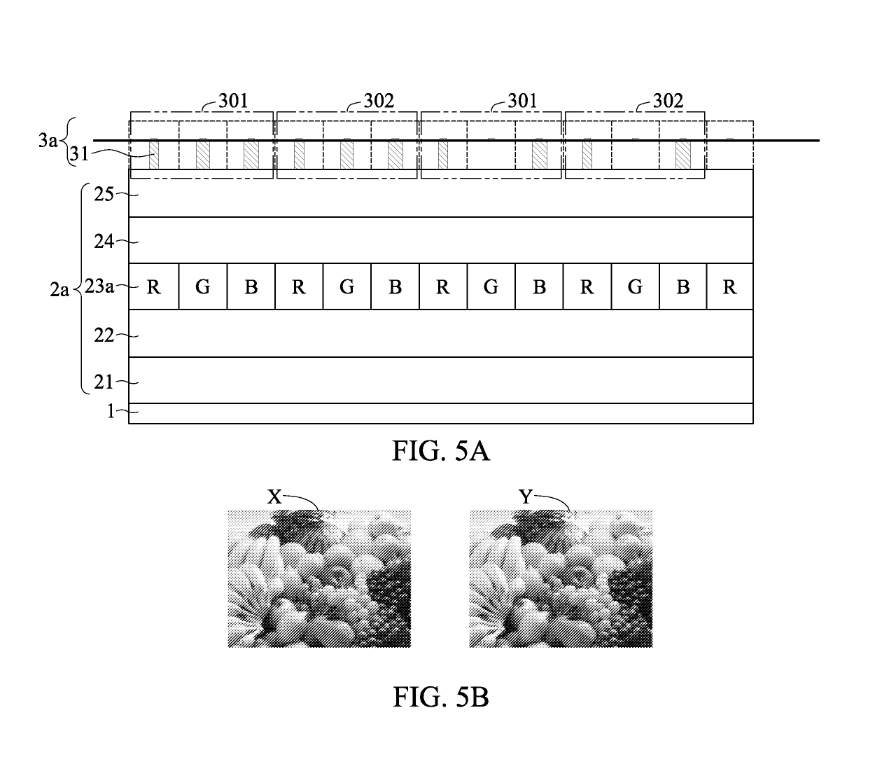

FIG. 5A is a schematic cross-sectional view of a light emitting device according to a fifth embodiment of the present disclosure. In the fifth embodiment, the electrode patterns 31 of the second electrode layer 3a are divided into a plurality of electrode pattern groups. The electrode pattern groups are arranged in an alternate manner and display a same image. Referring to FIG. 5A, the electrode patterns 31 are divided into a first electrode pattern group 301 and a second electrode pattern group 302 that are arranged in an alternate manner. When a first voltage is applied between the first electrode layer 1 and the second electrode layer 3a, the first electrode pattern group 301 displays an image X and the second electrode pattern group 302 displays an image Y that is the same as the image X, as shown in FIG. 5B. As such, when a viewer views different images from different viewing angles of the right and left eyes, his brain combines the different images from both eyes into a three-dimensional image.

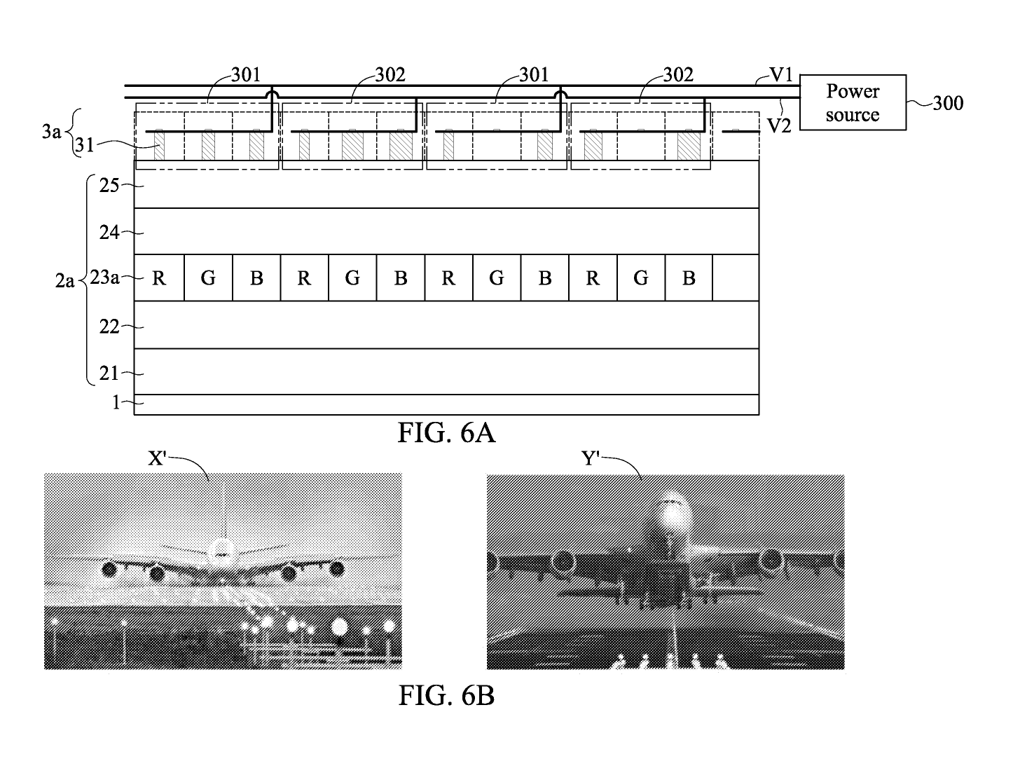

FIG. 6A is a schematic cross-sectional view of a light emitting device according to a sixth embodiment of the present disclosure, and FIG. 6B shows images displayed by the light emitting device according to the sixth embodiment of the present disclosure. The sixth embodiment differs from the fifth embodiment in that the electrode pattern groups of the light emitting device of the sixth embodiment display different images and a same or different voltages are applied to the electrode pattern groups at different times. Referring to FIG. 6A, a power source 300 supplies a first voltage V1 and a second voltage V2 to the first electrode pattern group 301 and the second electrode pattern group 302, respectively, at different times. In particular, referring to FIG. 6B, at a first time, the first voltage V1 is switched on and the second voltage V2 is switched off such that the first electrode pattern group 301 displays an image X′. At a second time, the first voltage V1 is switched off and the second voltage V2 is switched on such that the second electrode pattern group 302 shows an image Y′. As such, the light emitting device generates a dynamic image.

Further, the first voltage V1 or the second voltage V2 and the image can have a parallel type regular image circuit configuration, a parallel type irregular image circuit configuration, a series type regular image circuit configuration or a series type irregular image circuit configuration.

In the fifth and sixth embodiments, the electrode patterns 31 of the second electrode layer 3a have different sizes or pitches. The organic light emitting layer 2 is performed by a color separation process to be plurality of monochromatic blocks that correspond to the electrode patterns 31 of the second electrode layer 3a, respectively.

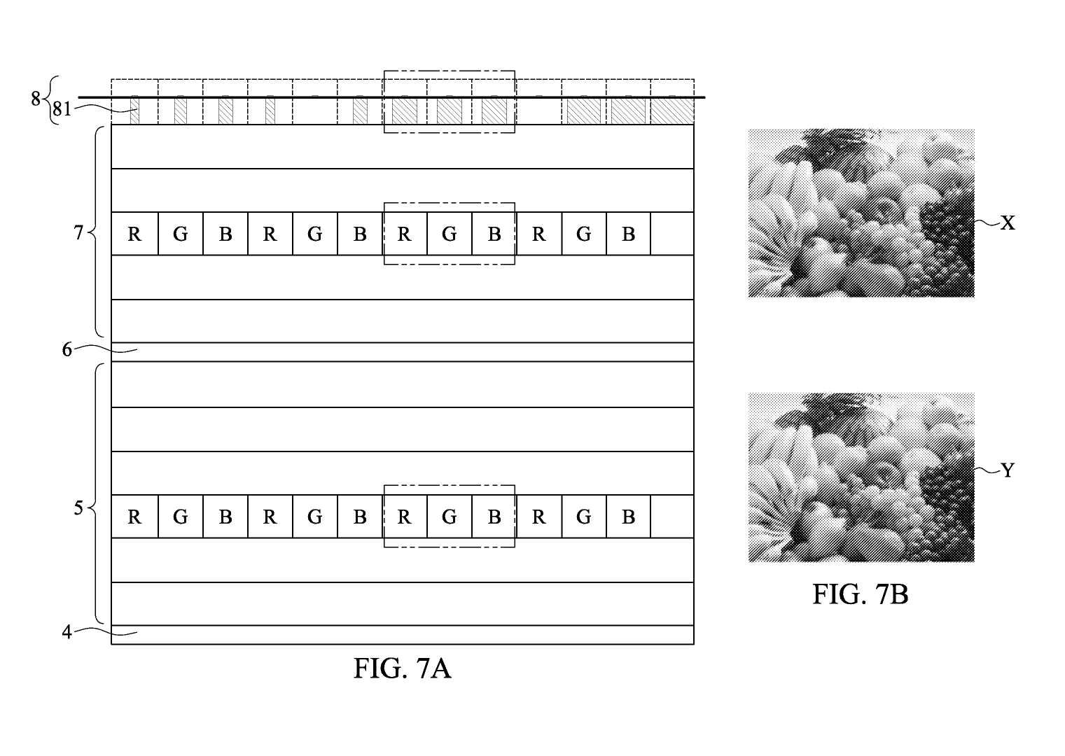

FIG. 7A is a schematic cross-sectional view of a light emitting device according to a seventh embodiment of the present disclosure, and FIG. 7B shows images displayed by the light emitting device according to the seventh embodiment of the present disclosure. Referring to FIG. 7A, the light emitting device of the seventh embodiment has a first electrode layer 4, a first organic light emitting layer 5, an electric charge generating layer 6, a second organic light emitting layer 7 and a second electrode layer 8 sequentially stacked on one another. The second electrode layer 8 is patterned to form a plurality of electrode patterns 81 that are arranged with different densities.

When a voltage is applied between the first electrode layer 4 and the second electrode layer 8, since both the first and second organic light emitting layers 5 and 7 correspond to the same patterned electrode layer 8, the light emitting device generates two identical images X, Y in a vertical direction, as shown in FIG. 7B. When the two images are viewed at different distances from a viewer, the two images have differences in brightness and color. As such, the two images are combined to generate a three-dimensional image.

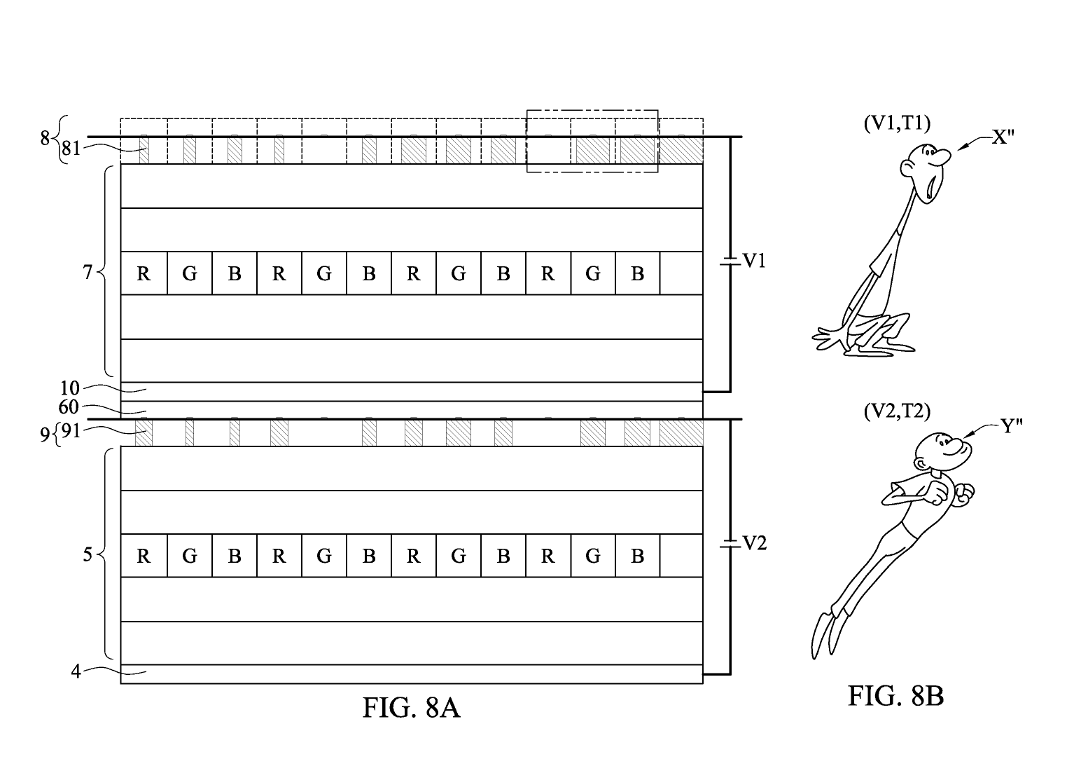

FIG. 8A is a schematic cross-sectional view of a light emitting device according to an eighth embodiment of the present disclosure, and FIG. 8B shows images displayed by the light emitting device according to the eighth embodiment of the present disclosure. Different from the seventh embodiment, the light emitting device of the eighth embodiment further has a third electrode layer 9, an insulating layer 60 and a fourth electrode layer 10 sequentially stacked between the first organic light emitting layer 5 and the second organic light emitting layer 7. Referring to FIG. 8A, the third electrode layer 9 is patterned to form a plurality of electrode patterns 91 arranged with different densities. The electrode patterns 91 of the third electrode layer 9 display an image Y″, and the electrode patterns 81 of the second electrode layer 8 display an image X″. Further, a same or different voltages are applied to the third electrode layer 9 and the second electrode layer 8 at different times.

At a first time T1, a first voltage V1 is applied between the second electrode layer 8 and the fourth electrode layer 10, and at a second time T2, a second voltage V2 is applied between the third electrode layer 9 and the first electrode layer 4, thus generating a dynamic image, as shown in FIG. 8B.

In the seventh and eighth embodiments, the electrode patterns 81 of the second electrode layer 8 have different sizes or pitches, and the electrode patterns 91 of the third electrode layer 9 have different sizes or pitches. The first organic light emitting layer 5 and the second organic light emitting layer 7 are preformed by a color separation process to be a plurality of monochromatic blocks. The electrode patterns 81 of the second electrode layer 8 and the electrode patterns 91 of the third electrode layer 9 correspond to the monochromatic blocks.

According to the present disclosure, the second electrode layer, i.e., the cathode electrode layer, is patterned to form a plurality of electrode patterns arranged with different densities. As such, when a voltage is applied between the first electrode layer and the second electrode layer, the light emitting device of the present disclosure generates a grayscale image, thereby eliminating the need to control each pixel through a thin film transistor as in the prior art. Further, the organic light emitting layer can be performed by a color separation process to be a plurality of R, G and B monochromatic blocks. Since the electrode patterns have different sizes or pitches, the light emitting device can generate a full-color/grayscale image. Furthermore, by arranging the electrode patterns in a vertical direction or a horizontal direction and applying voltages of suitable values and time sequences on the electrode layers, the light emitting device of the present disclosure can generate a three-dimensional or dynamic image.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light emitting device, comprising:
a first electrode layer;
an organic light emitting layer disposed on the first electrode layer; and
a second electrode layer disposed on the organic light emitting layer,
wherein the organic light emitting layer is sandwiched between the first electrode layer and the second electrode layer, and the second electrode layer is patterned to form a plurality of electrode patterns arranged with different densities.

2. The light emitting device of claim 1, wherein a voltage is applied between the first electrode layer and the second electrode layer.

3. The light emitting device of claim 1, wherein the electrode patterns have different sizes or pitches.

4. The light emitting device of claim 1, wherein the organic light emitting layer is performed by a color separation process to be a plurality of monochromatic blocks that correspond to the electrode patterns, respectively.

5. A light emitting device, comprising:
a first electrode layer;
an organic light emitting layer disposed on the first electrode layer; and
a second electrode layer disposed on the organic light emitting layer,
wherein the organic light emitting layer is sandwiched between the first electrode layer and the second electrode layer, the second electrode layer is patterned to form a plurality of electrode patterns arranged with different densities, and the electrode patterns are divided into a plurality of electrode pattern groups that are arranged in an alternate manner.

6. The light emitting device of claim 5, wherein the electrode pattern groups display a same image, and a same voltage is applied to the electrode pattern groups at a same time.

7. The light emitting device of claim 5, wherein the electrode pattern groups display different images, and a same or different voltages are applied to the electrode pattern groups at different times.

8. The light emitting device of claim 5, wherein the electrode patterns have different sizes or pitches.

9. The light emitting device of claim 5, wherein the organic light emitting layer is preformed by a color separation process to be a plurality of monochromatic blocks that corresponds to the electrode patterns, respectively.

10. A light emitting device, comprising:
a first electrode layer;
a first organic light emitting layer disposed on the first electrode layer;
a second organic light emitting layer deposed on the first organic light emitting layer; and
a second electrode layer disposed on the second organic light emitting layer,
wherein the first organic light emitting layer is sandwiched between the first electrode layer and the second organic light emitting layer, the second organic light emitting layer is sandwiched between the second electrode layer and the first organic light emitting layer, and the second electrode layer is patterned to form a plurality of electrode patterns arranged with different densities.

11. The light emitting device of claim 10, further comprising an electric charge generating layer disposed between the first organic light emitting layer and the second organic light emitting layer.

12. The light emitting device of claim 10, wherein a voltage is applied between the first electrode layer and the second electrode layer.

13. The light emitting device of claim 10, further comprising a third electrode layer, an insulating layer and a fourth electrode layer that are sequentially stacked between the first organic light emitting layer and the second organic light emitting layer, wherein the third electrode layer is patterned to form a plurality of electrode patterns arranged with different densities, the electrode patterns of the second electrode layer display an image that is different from an image displayed by the electrode patterns of the third electrode layer, and a same or different voltages are applied to the second electrode layer and the third electrode layer at different times.

14. The light emitting device of claim 13, wherein the electrode patterns of the second electrode layer have different sizes or pitches, and the electrode patterns of the third electrode layer have different sizes or pitches.

15. The light emitting device of claim 13, wherein the first organic light emitting layer and the second organic light emitting layer are performed by a color separation process to be a plurality of monochromatic blocks that correspond to the electrode patterns of the second electrode layer and the third electrode layer, respectively.
